(19) United States
(12) Patent Application Publication
(10) Pub. No.: US 2014/0366367 A1
(43) Pub. Date: Dec. 18, 2014

(54) MOUNTING APPARATUS FOR FAN

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: ZHAN-YANG LI, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/244,234

(22) Filed: Apr. 3, 2014

(30) Foreign Application Priority Data
Jun. 14, 2013 (CN) 2013102353605

(51) Int. Cl. G06F 1/20; F04D 29/60; H05K 7/20

(52) U.S. Cl. CPC G06F 1/20; H05K 7/20136; F04D 29/601
USPC 29/700

(57) ABSTRACT

A mounting apparatus includes a platform, a moving device, and a pressing device. The moving device includes a first moving member. The pressing device includes a first pressing member rotatably attached to the platform, and the first pressing member abuts the first moving member and used to position a first side plate of a fan. The first moving member is movable relative to the platform between a first position and a second position. In the first position, the first pressing member is substantially parallel to the platform, and the first moving member is located on a first side of the platform. In the second position, the first pressing member is substantially perpendicular to the platform to engage the first side plate to the fan, and the first moving member is located on a second opposite side of the platform.

### FIELD

The present disclosure relates to mounting apparatuses, and particularly to a mounting apparatus for securing side plates to a fan.

### BACKGROUND

In a working computer system, a large amount of heat may be generated from electrical elements of the computer system. A fan is used as a conventional means to dissipate the heat out of the computer system. Typically, a bracket is provided for receiving a fan, and a plurality of screws may be used to install the bracket to the fan. In such a configuration, assembling and disassembling of the fan may be inconvenient.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. In the drawings, like reference numerals designate corresponding parts throughout the several views.

FIG. 1 is an exploded, isometric view of a mounting apparatus and a fan in accordance with an embodiment.

FIG. 2 is an enlarged view of a circled portion II of the mounting apparatus of FIG. 1.

FIG. 3 is similar to FIG. 1, but viewed from a different aspect.

FIG. 4 is an assembled view of the mounting apparatus of FIG. 1.

FIG. 5 is an assembled view of the mounting apparatus and the fan of FIG. 1, the two first side plates and two second side plates not being secured to the fan.

FIG. 6 is another assembled view of the mounting apparatus and the fan of FIG. 1, the two first side plates are secured to the fan, and the two second side plates are not secured to the fan.

FIG. 7 is similar to FIG. 6, and the two first side plates and the two second side plates are secured to the fan.

FIG. 8 is similar to FIG. 5, and the two first side plates and the two second side plates are secured to the fan.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

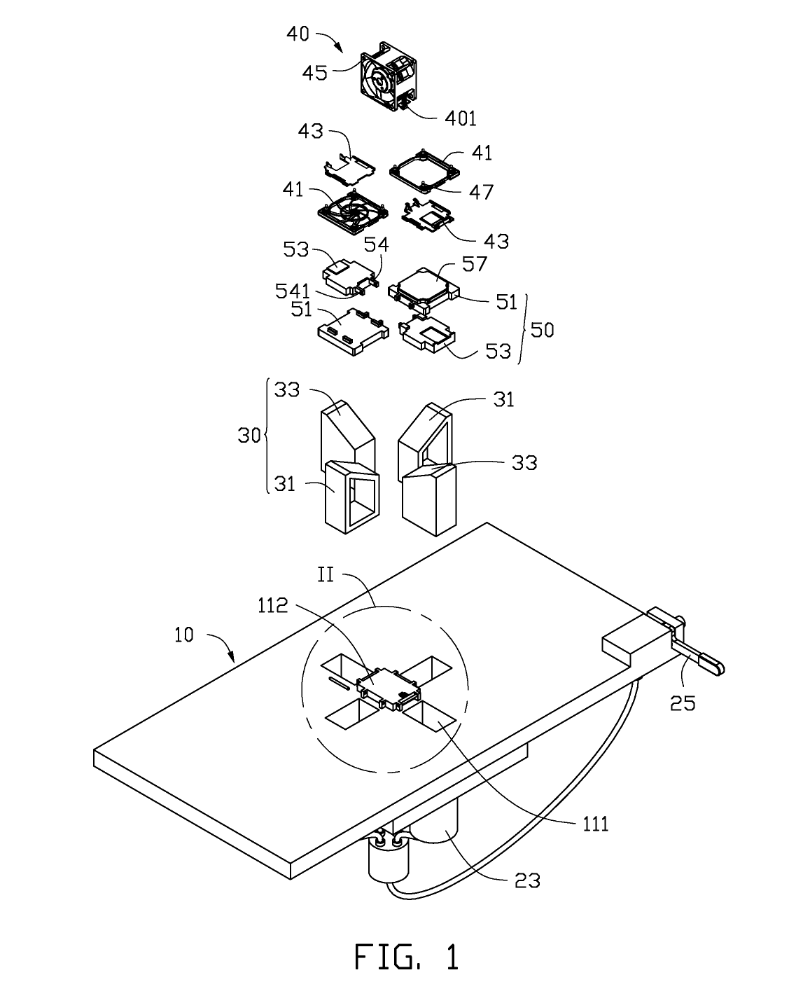

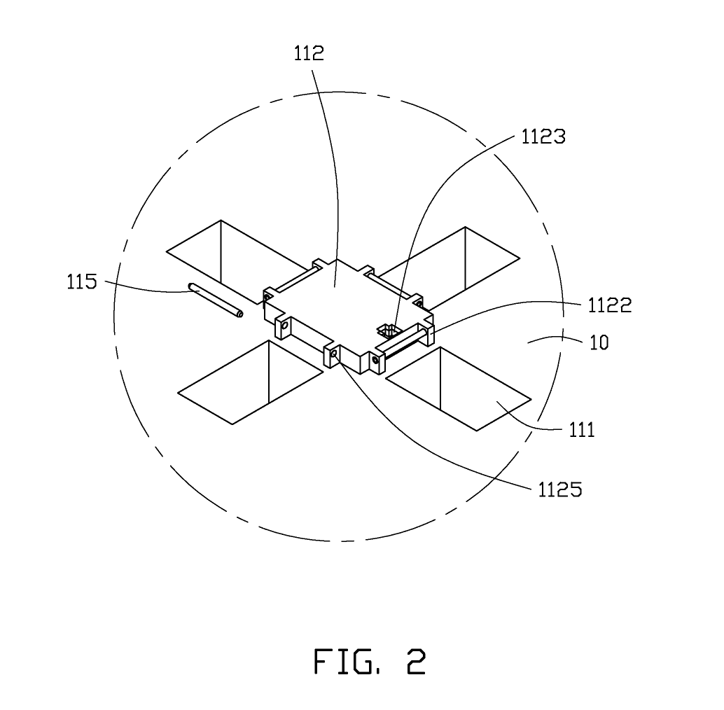

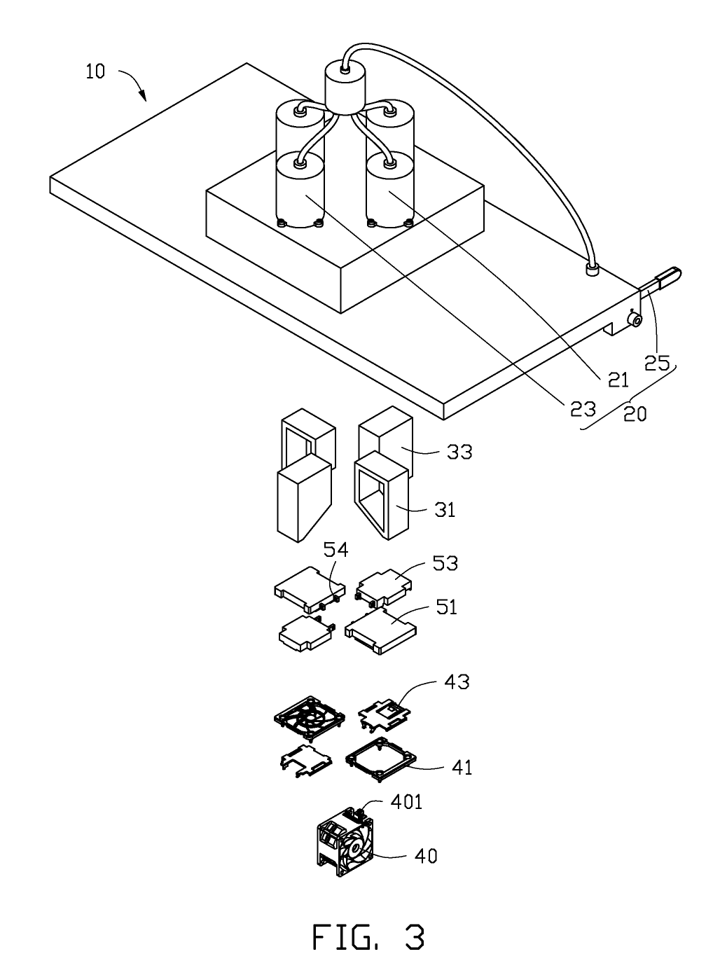

FIGS. 1-3 illustrate a mounting apparatus in accordance with an embodiment. The mounting apparatus comprises a platform 10, a driving device 20 attached to the platform 10, a moving device 30 movably attached to the platform 10, and a pressing device 50 rotatably attached to the platform 10. The mounting apparatus is used to mount two opposite first side plates 41 and two opposite second side plates 43 to a fan 40. A plurality of positioning holes 45 is defined in the fan 40, and a plurality of positioning posts 47 is located on each of the two first side plates 41 and on two second side plates 43 to correspond to the plurality of positioning holes 45. The fan 40 comprises an inserting portion 401.

A positioning base 112 protrudes from the platform 10. The positioning base 112 is substantially a rectangle. Two retaining pieces 1122, each with a retaining hole 1125, extend from each edge of the positioning base 112. The positioning base 112 defines a receiving slot 1123. Four through holes 111 are defined in the platform 10 and around the positioning base 112.

The driving device 20 comprises two first driving members 21, two second driving members 23, and a switch 25. The two first driving members 21 and the two second driving members 23 are located on a bottom surface of the platform 10. The switch 25 is used to power on or power off the two first driving members 21 and the two second driving members 23. In one embodiment, each of the two first driving members 21 and the two second driving members 23 is an air cylinder, and a pushing force generated by each of the two first driving members 21 and the two second driving members 23 is the same.

The moving device 30 comprises two first opposite moving members 31 and two second opposite moving members 33. The two first moving members 31 and the two second moving members 33 extend through the four through holes 111 to abut the two first driving members 21 and the two second driving members 23 respectively. Each of the two first opposite moving members 31 and the two second opposite moving members 33 comprises a slanted surface 35. In one embodiment, a weight of each first moving member 31 is less than a weight of each second moving member 33.

The pressing device 50 comprises two first opposite pressing members 51 and two second opposite pressing members 53. Each of the two first pressing members 51 and the two second opposite pressing members 53 comprises two securing arms 54. Each securing arm 54 defines a securing hole 541. In one embodiment, a plurality of positioning portions 57 are located on each of the two first pressing members 51 and the two second opposite pressing members 53, to position the first and second side plates 41, 43.

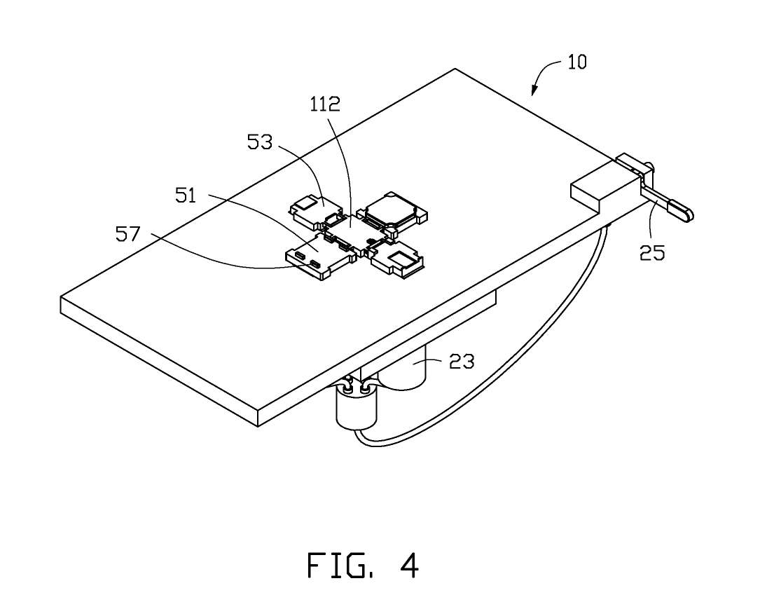

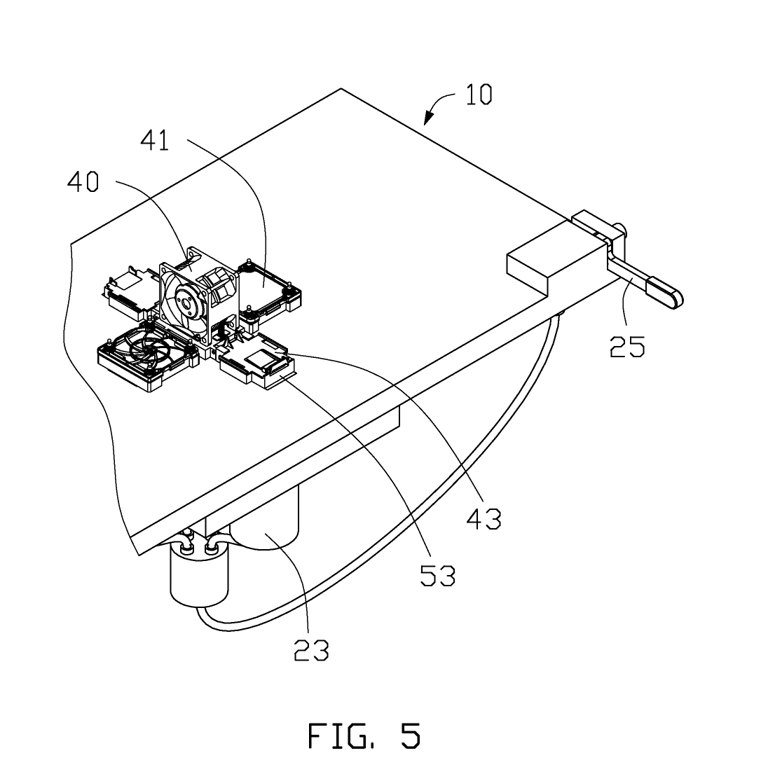

FIGS. 4-8 illustrate assembly of the mounting apparatus of an embodiment. The two first moving members 31 and the two second moving members 33 extend through the through holes and abut the first driving members and the two second driving members 23. Each of the first and second pressing members 51, 53 is located on the platform 10 and abuts on each of the two first moving members 31 and the two second moving members 33. Therefore, the first and second pressing members 51, 53 can be moved through the through holes by the first driving members and the two second driving members 23. Each securing arm abuts each retaining piece, and the securing hole is aligned with the retaining hole. A securing post is engaged in the securing hole and the retaining hole, to rotatably secure each of the first and second pressing members 51, 53 to the positioning base 112.

The moving device 50 is moveable relative to the platform 10 to and from a first position and a second position. In the first position, the moving device is located on a bottom surface of the platform 10, and each of the first and second pressing members 51, 53 is substantially parallel to the platform 10. In the second position, the moving device is located on a top surface of the platform 10, and each of the first and second pressing members 51, 53 is substantially perpendicular to the platform 10.

In use, the moving device 50 is located at the first position. The first and second side plates 41, 43 are placed on the first and second pressing members 51, 53 respectively. The positioning portions 57 are engaged with the portions (not shown) on the first and second side plates 41, 43 so as to prevent the first and second side plates 41, 43 from disengaging from the first and second pressing members 51, 53. The fan 40 is located on the positioning base 112, and the inserting portion is engaged in the receiving slot.

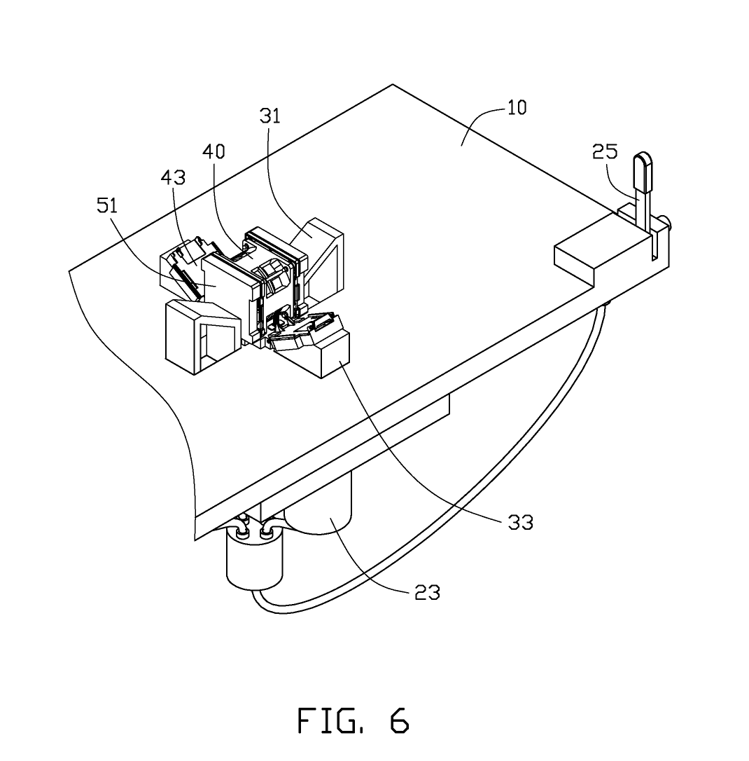

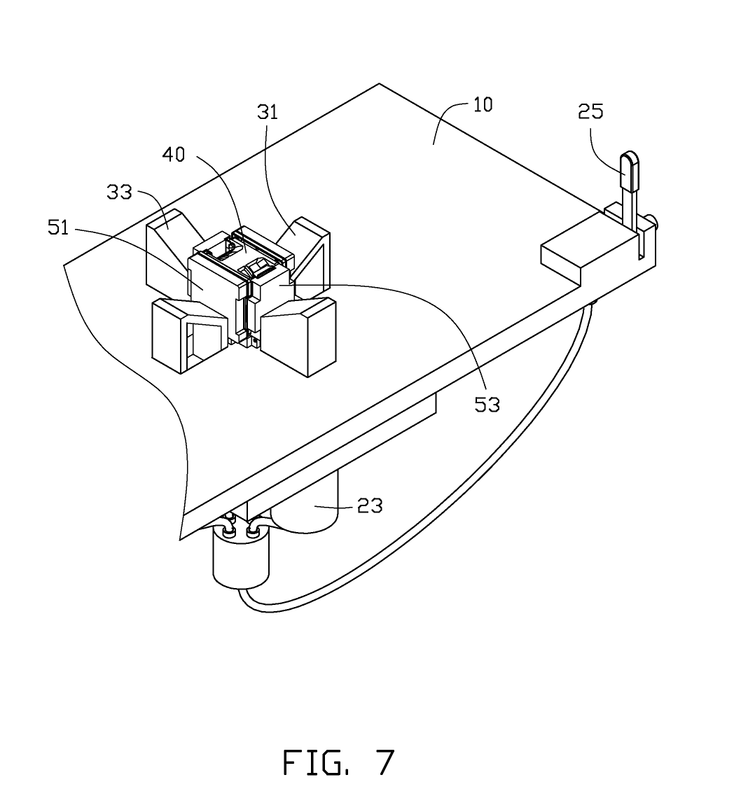

The switch is switched on, and the first and second driving members 21, 23 are powered on to move the first and second moving members 31, 33 upward to extend through the through holes. The first and second side plates 41, 43 are moved towards the fan 40 by the first and second pressing members 51, 53, until the positioning posts are engaged in a positioning hole. Thus, the first and second side plates 41, 43 are secured to the fan 40. The weight of each first moving member 31 is less than the weight of each second moving member 33, and a moving speed of each first moving member 31 is greater than a moving speed of each second moving member 33. Therefore, the two first side plates 41 can be secured to the fan 40 first, and the two second side plates 43 can be secured to the fan 40 second (see FIGS. 6-7).

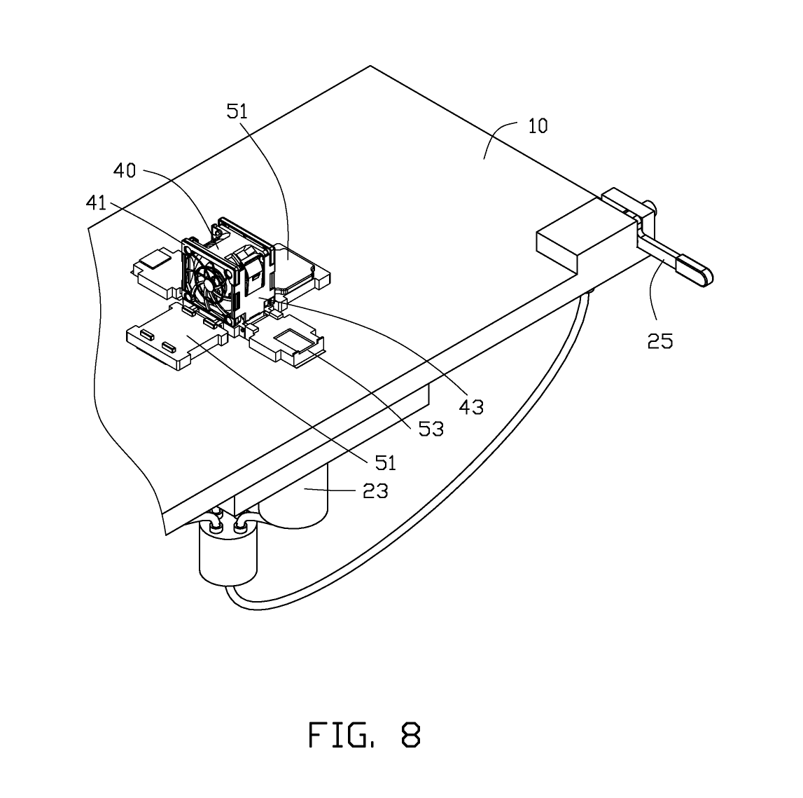

The switch is switched off, and the first and second driving members 21, 23 are powered off to move the first and second moving members 31, 33 downward to extend through the through holes. When the moving device is located on the first position (see FIG. 8), the inserting portion is disengaged from the receiving slot, and the fan 40 can be detached from the positioning base 112.

It is to be understood, however, that even though numerous characteristics and advantages have been set forth in the foregoing description of embodiments, together with details of the structures and functions of the embodiments, the disclosure is illustrative only and changes may be made in detail, including in the matters of shape, size, and arrangement of parts within the principles of the disclosure. The embodiments described herein do not limitation the scope of the following claims.

What is claimed is:

1. A mounting apparatus comprising:
a platform;
a moving device comprising a first moving member; and
a pressing device comprising a first pressing member rotatably attached to the platform; the first pressing member abutting the first moving member and configured for positioning a first side plate of a fan;
wherein the first moving member is movable relative to the platform between a first position and a second position; when the first moving member is in the first position, the first pressing member is substantially parallel to the platform, and the first moving member is located on a first side of the platform; when the first moving member is in the second position, the first pressing member is substantially perpendicular to the platform to engage the first side plate to the fan, and the first moving member is located on a second opposite side of the platform.

2. The mounting apparatus of claim 1, further comprising a driving device; wherein the driving device is attached to the first moving member, and the first moving member is movable in a direction that is substantially perpendicular to the platform by the driving device.

3. The mounting apparatus of claim 2, wherein the driving member comprises a first driving member and a second driving member, the moving device further comprises a second moving member; the pressing device further comprises a second pressing member, the first moving member is attached to the first driving member, and the second moving member is attached to the second driving member and configured for positioning a second side plate of a fan.

4. The mounting apparatus of claim 3, wherein a weight of each first moving member weighs less than each second moving member.

5. The mounting apparatus of claim 1, wherein the first moving member comprises a slanted surface, and the slanted surface is configured to be attached to the first side plate.

6. The mounting apparatus of claim 1, wherein the platform comprises a positioning base configured to position the fan, and the first pressing member is rotatably engaged with the positioning base.

7. The mounting apparatus of claim 6, wherein the positioning base comprises a retaining piece, the retaining piece defines a retaining hole, the first pressing member comprises a securing piece, the securing piece defines a securing hole, and a securing post is engaged in the securing hole and the retaining hole, thereby rotatably securing the first pressing member to the positioning base.

8. The mounting apparatus of claim 1, wherein the platform defines a through hole, and the first moving member is moveably received in the through hole.

9. A mounting apparatus comprising:
a platform defining a through hole;
a moving device comprising a first moving member moveably received in the through hole; and
a driving device comprising a first driving member attached to the first moving member;
a pressing device comprising a first pressing member rotatably attached to the platform; the first pressing member abutting the first moving member and configured for positioning a first side plate of a fan;
wherein the first moving member is moveable to extend through the through hole by the first driving member, for allowing the first pressing member to secure the first side plate to the fan.

10. The mounting apparatus of claim 9, wherein the first moving member is movable in a direction that is substantially perpendicular to the platform.

11. The mounting apparatus of claim 9, wherein the driving member further comprises a second driving member, the moving device further comprises a second moving member; the pressing device further comprises a second pressing member, the first moving member is attached to the first driving member, and the second moving member is attached to the second driving member and configured for positioning a second side plate of a fan.

12. The mounting apparatus of claim 11, wherein a weight of each first moving member weighs less than each second moving member.

13. The mounting apparatus of claim 9, wherein the first moving member comprises a slanted surface, and the slanted surface is configured to be attached to the first side plate.

14. The mounting apparatus of claim 9, wherein the platform comprises a positioning base configured to position the fan, and the first pressing member is rotatably engaged with the positioning base.

15. The mounting apparatus of claim 14, wherein the positioning base comprises a retaining piece, the retaining piece defines a retaining hole, the first pressing member comprises a securing piece, the securing piece defines a securing hole, and a securing post is engaged in the securing hole and the retaining hole, thereby rotatably securing the first pressing member to the positioning base.

16. The mounting apparatus of claim 9, wherein the first pressing member comprises a positioning portion, and the positioning portion is configured to position the first side plate.
